(19) United States
(12) Patent Application Publication
(10) Pub. No.: US 2026/0068122 A1
(43) Pub. Date: Mar. 5, 2026

(54) SEMICONDUCTOR STRUCTURE AND FABRICATION METHOD THEREFOR

(71) Applicant: CXMT Corporation, Hefei City (CN)

(72) Inventors: Yali TAN, Hefei City (CN); Huihui LI, Hefei City (CN); Zihao YUAN, Hefei City (CN); Yi TANG, Hefei City (CN)

(73) Assignee: CXMT Corporation, Hefei City (CN)

(21) Appl. No.: 19/287,708

(22) Filed: Jul. 31, 2025

Related U.S. Application Data
(63) Continuation of application No. PCT/CN2025/076599, filed on Feb. 10, 2025.

(30) Foreign Application Priority Data
Aug. 27, 2024 (CN) 202411195334.9

(51) Int. Cl. H10B 12/00

(52) U.S. Cl. CPC H10B 12/30; H10B 12/03; H10B 12/05

(57) ABSTRACT

A semiconductor structure and a fabrication method therefor are provided. The fabrication method includes: A substrate and a stacked structure formed on the substrate are provided; vias running through the stacked structure in the vertical direction are formed; a sidewall protective layer is formed on an inner wall of each of the vias; a bottom protective layer is formed on the partial surface of the substrate exposed by each of the vias; each of the vias is filled with an isolation layer; the isolation layer s and a part of the sidewall protective layer in each of the first hole are removed, and a transistor structure is formed in each of the first holes; and the isolation layer and a part of the sidewall protective layer in each of the second holes are removed, and a capacitor structure is formed in each of the second holes.

### CROSS-REFERENCE TO RELATED APPLICATIONS

The present application is a continuation of International Patent Application No. PCT/CN2025/076599 filed on Feb. 10, 2025, which claims priority to Chinese Patent Application No. 202411195334.9 filed on Aug. 27, 2024. The disclosures of the above-referenced applications are hereby incorporated by reference in their entirety.

### BACKGROUND

The development of a dynamic random access memory (DRAM) targets performance indicators such as high speed, high integration density, and low power consumption. With miniaturization of semiconductor device structure sizes, technical barriers encountered by existing structures become increasingly obvious. Therefore, developing more novel structures based on the basis of the existing structure is an advantageous means to break existing technical barriers.

The emergence of three-dimensional dynamic random access memory (3D DRAM), in particular, 3D DRAM incorporating a multilayer horizontal cell (MHC), which usually includes multiple transistors and multiple capacitors stacked on a substrate, meets the foregoing requirements.

However, in the procedure of fabricating structures such as a transistor and a capacitor, an etching process is prone to cause a damage to the substrate or a risk of impurity peeling. Consequently, the device performance of the structures such as the transistor and the capacitor is affected, and the stability of the dynamic random access memory is reduced.

### SUMMARY

Embodiments of the present disclosure relate to the field of semiconductor technologies, and in particular, to a semiconductor structure and a fabrication method therefor.

According to some embodiments of the present disclosure, a fabrication method for a semiconductor structure is provided, including the steps as follows. A substrate and a stacked structure formed on the substrate are provided, where the stacked structure includes first dielectric layers and second dielectric layers stacked in the vertical direction. Vias running through the stacked structure in the vertical direction are formed, where the vias include first holes and second holes, each of the vias exposes a partial surface of the substrate, and the bottom surface of each of the vias is flush with or lower than the top surface of the substrate. A sidewall protective layer is formed on an inner wall of each of the vias. A bottom protective layer is formed on the partial surface of the substrate exposed by each of the vias. Each of the vias is filled with an isolation layer. The isolation layer and a part of the sidewall protective layer in each of the first holes are removed, and a transistor structure is formed in each of the first holes. The isolation layer and a part of the sidewall protective layer in each of the second holes are removed, and a capacitor structure is formed in each of the second holes, where the capacitor structure is electrically connected to the transistor structure.

According to some embodiments of the present disclosure, a semiconductor structure is provided, including: a substrate and a stacked structure located on the surface of the substrate, where the stacked structure includes first dielectric layers and second dielectric layers stacked in the vertical direction; vias running through the stacked structure in the vertical direction, where the vias include first holes and second holes; a bottom protective layer located at a bottom of each of the vias and a sidewall protective layer surrounding the bottom protective layer, where the bottom protective layer is in contact with the substrate; a transistor structure located in each of the first holes; and a capacitor structure located in each of the second holes, where the capacitor structure is electrically connected to the transistor structure.

In the embodiments of the present disclosure, the bottom protective layer located at the bottom of each of the vias and the sidewall protective layer are disposed, and the bottom protective layer and the sidewall protective layer are utilized to protect the substrate, to avoid damage to the substrate when the isolation layer is removed, and reduce the possibility of electric leakage of the transistor structure and the capacitor structure, thereby improving the performance stability of the semiconductor structure.

### BRIEF DESCRIPTION OF DRAWINGS

FIG. 1 is a flowchart of a fabrication method for a semiconductor structure according to an example embodiment;

FIG. 2 to FIG. 5 are schematic diagrams of a procedure of fabricating a semiconductor structure in which vias are formed according to an example embodiment;

FIG. 6 to FIG. 7 are schematic diagrams of a procedure of fabricating a semiconductor structure in which a bottom protective layer and an isolation layer are formed in a via according to an example embodiment;

FIG. 8 to FIG. 10 are schematic diagrams of a procedure of fabricating a semiconductor structure in which a bottom protective layer and an isolation layer are formed in a via according to another example embodiment;

FIG. 11 to FIG. 13 are schematic diagrams of a procedure of fabricating a semiconductor structure in which a bottom protective layer and an isolation layer are formed in a via according to another example embodiment; and

FIG. 14 to FIG. 21 are schematic diagrams of a procedure of fabricating a semiconductor structure in which a transistor structure and a capacitor structure are formed in a via according to an example embodiment.

### DESCRIPTIONS OF REFERENCE NUMERALS

10—semiconductor structure; 110—substrate; 110R—substrate recess; 120—stacked structure; 121—first dielectric layer; 122—second dielectric layer; 130—via; 131—first hole; 132—second hole; 130G—via group; 210—sidewall protective material layer; 211—sidewall protective layer; 311—bottom protective layer; 311a—monocrystalline silicon layer; 311b—silicon germanium layer; 320—isolation layer; 411—mask layer; 411T—linear trench; 412—bit line structure; 412T—bit line trench; 413—third dielectric layer; 510—capacitor structure; 510C—capacitor unit; 510T—capacitor trench; 511—bottom electrode layer; 511a—upper parallel portion; 511b—lower parallel portion; 511c—vertical portion; 512—capacitor dielectric layer; 513—upper electrode layer; 513a—first upper electrode layer; 513b—second upper electrode layer; 610—transistor structure; 610C—transistor unit; 611—channel layer; 612—gate dielectric layer; 613—gate structure; X—first direction; Y—second direction; Z—vertical direction.

### DETAILED DESCRIPTION

The technical solutions of the present disclosure are further described below in detail with reference to the accompanying drawings and the embodiments. Although example implementation methods of the present disclosure are shown in the accompanying drawings, it should be understood that the present disclosure may be implemented in various forms without being limited by the implementations described herein. Instead, these implementations are provided to develop a more thorough understanding of the present disclosure and to fully convey the scope of the present disclosure to a person skilled in the art.

In the following paragraphs, the present disclosure is described more specifically by way of example with reference to the accompanying drawings. The advantages and features of the present disclosure will be clearer from the following description and claims. It should be noted that the accompanying drawings are presented in a highly simplified form and are not to exact scale, and are merely intended to conveniently and clearly assist in describing the embodiments of the present disclosure.

It may be understood that meanings of “on”, “over”, and “above” in the present disclosure should be understood in the broadest sense, so that “on” means that it is “on” something with no intermediate feature or layer (that is, directly on something), and further includes the meaning that it is “on” something with an intermediate feature or layer.

In the embodiments of the present disclosure, the terms “first”, “second”, “third”, and the like are intended to distinguish between similar objects but do not necessarily describe a specific order or sequence.

In the embodiments of the present disclosure, the term “layer” refers to a material part including a region having a thickness. The layer may extend over the whole of a lower or upper structure, or may have a range smaller than the range of the lower or upper structure. In addition, the layer may be a region of a homogeneous or heterogeneous continuous structure whose thickness is less than the thickness of a continuous structure. For example, the layer may be located between the top surface and the bottom surface of the continuous structure, or the layer may be located between any horizontal surface pair at the top surface and the bottom surface of the continuous structure. The layer may extend horizontally, vertically, and/or along an inclined surface. The layer may include multiple sublayers.

It should be noted that the technical solutions described in the embodiments of the present disclosure may be randomly combined when there is no conflict.

In some embodiments, in a procedure of fabricating structures such as a transistor and a capacitor on a substrate, a dielectric layer and a sacrificial material are formed on the substrate, and the sacrificial material in the dielectric layer is removed by an etching process to form a via exposing the surface of the substrate. However, it is found that, in actual fabrication, because the sacrificial material needs to have a relatively high etching selectivity with the dielectric layer, etching selectivity of the sacrificial material and the substrate that are commonly adopted are close to each other. However, in a procedure of removing the sacrificial material in the via or in a procedure of cleaning the via, it is prone to cause a damage to the substrate or a risk of impurities to peel off from the bottom of the via and a sidewall of the substrate. Consequently, the device performance of the structures such as the transistor and the capacitor that are subsequently formed on the surface of a damaged substrate is affected, and the overall performance stability and the structure stability of a semiconductor structure are reduced.

Based on this, to resolve the foregoing problem, an embodiment of the present disclosure provides a fabrication method for a semiconductor structure 10.

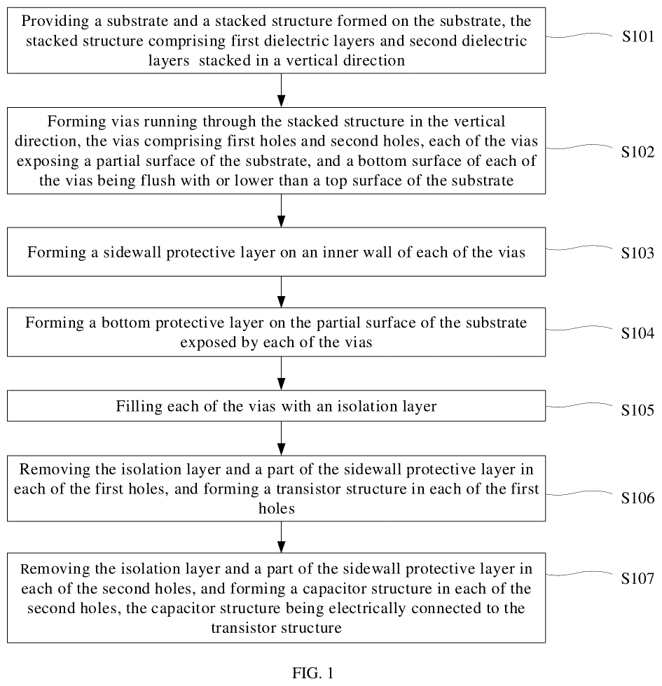

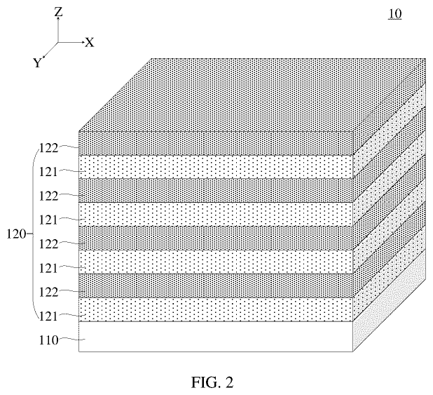

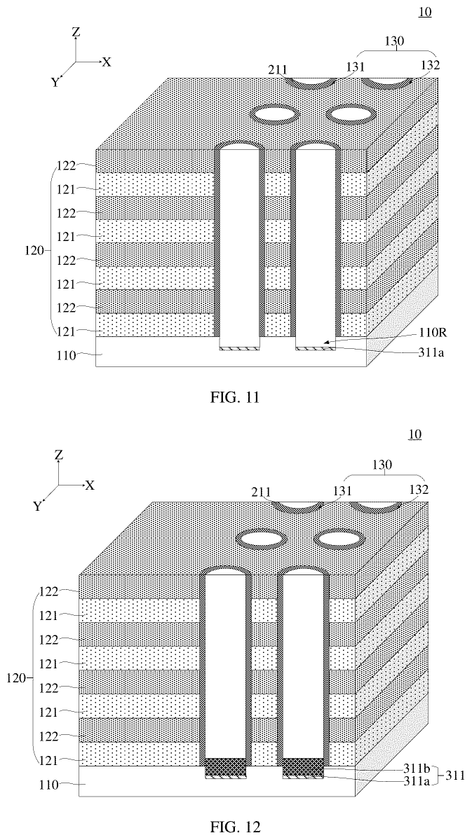

FIG. 1 is a flowchart of a fabrication method for a semiconductor structure according to an example embodiment. FIG. 2 to FIG. 7 and FIG. 14 to FIG. 21 are schematic diagrams of a fabrication procedure of a semiconductor structure according to an example embodiment. FIG. 8 to FIG. 10 are schematic diagrams of a fabrication procedure of a semiconductor structure according to another example embodiment. FIG. 11 to FIG. 13 are schematic diagrams of a fabrication procedure of a semiconductor structure according to another example embodiment. The following describes the semiconductor structure 10 and the fabrication procedure of the semiconductor structure 10 with reference to FIG. 1 and FIG. 2 to FIG. 21.

It may be understood that, in FIG. 2 to FIG. 21, a first direction X and a second direction Y are horizontal directions parallel to the plane in which a substrate 110 is located, and the first direction X intersects the second direction Y. For example, the first direction X may be perpendicular to the second direction Y. The vertical direction Z is a direction that intersects the plane in which the substrate 110 is located. For example, the vertical direction Z is perpendicular to the plane in which the substrate 110 is located.

As shown in FIG. 1, the fabrication method for a semiconductor structure provided in the present disclosure includes at least the following steps.

In the step of S101: Providing a substrate and a stacked structure formed on the substrate, the stacked structure comprising first dielectric layers and second dielectric layers stacked in a vertical direction.

In the step of S102: Forming vias running through the stacked structure in the vertical direction, the vias comprising first holes and second holes, each of the vias exposing a partial surface of the substrate, and a bottom surface of each of the vias being flush with or lower than a top surface of the substrate.

In the step of S103: Forming a sidewall protective layer on an inner wall of each of the vias.

In the step of S104: Forming a bottom protective layer on the partial surface of the substrate exposed by each of the vias.

In the step of S105: Filling each of the vias with an isolation layer.

In the step of S106: Removing the isolation layer and a part of the sidewall protective layer in each of the first holes, and forming a transistor structure in each of the first holes.

In the step of S107: Removing the isolation layer and a part of the sidewall protective layer in each of the second holes, and forming a capacitor structure in each of the second holes, the capacitor structure being electrically connected to the transistor structure.

It should be understood that the steps shown in FIG. 1 are not exclusive, and another step may be performed before, after, or between any steps in the operations shown. The sequence of the steps shown in FIG. 1 may be adjusted according to an actual requirement.

As shown in FIG. 2, a stacked structure 120 is formed on the substrate 110, and the stacked structure 120 includes first dielectric layers 121 and second dielectric layers 122 alternately stacked in the vertical direction. The material of the substrate 110 may include silicon, e.g., monocrystalline silicon, polycrystalline silicon, or amorphous silicon.

The materials of the first dielectric layers 121 and the materials of the second dielectric layers 122 are different, which may be two types of insulating materials such as silicon oxide, silicon nitride, silicon oxynitride, and silicon carbide. The first dielectric layers 121 and the second dielectric layers 122 may be alternately formed by a deposition process. The deposition process may include chemical vapor deposition (CVD), an atomic layer deposition (ALD) process, plasma enhanced ALD, physical vapor deposition (PVD), plasma enhanced chemical vapor deposition (PECVD), low pressure chemical vapor deposition (LPCVD), or the like. In an example, one of the first dielectric layers 121 covers the top surface of the substrate 110, that is, the bottom layer of the stacked structure 120 is one of the first dielectric layers 121, and the top layer of the stacked structure 120 may be one of the second dielectric layers 122.

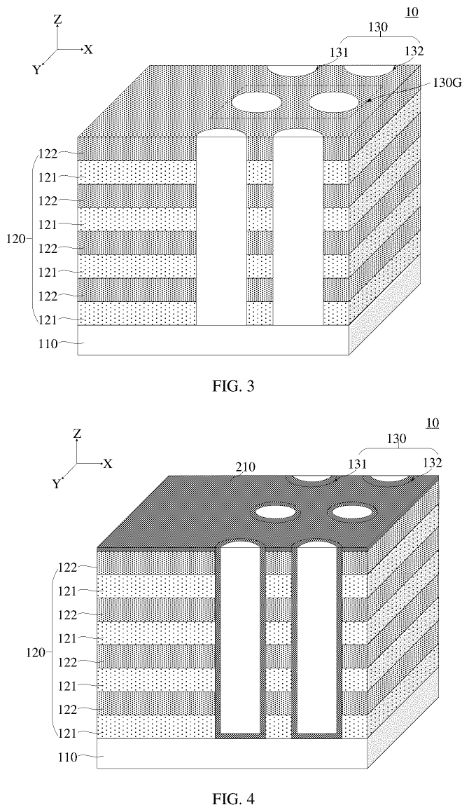

As shown in FIG. 3, vias 130 running through the stacked structure 120 in the vertical direction are formed, the bottom of each of the vias 130 exposes a part of the surface of the substrate 110, and the bottom surface of each of the vias 130 may be flush with the top surface of the substrate 110. In another example, a part of the substrate 110 may alternatively be removed, so that the bottom surface of each of the vias 130 is lower than the top surface of the substrate 110.

The vias 130 include first holes 131 and second holes 132, each of the first holes 131 is configured to form a plurality of transistors, and each of the second holes 132 is configured to form a plurality of capacitors. A cross-section of each of the first holes 131 and the second holes 132 in the vias 130 on a horizontal plane formed by a first direction X and a second direction Y may be circular, oval, or rectangular. Multiple first holes 131 may be arranged at intervals in the second direction Y, and multiple second holes 132 may be arranged at intervals in the second direction Y. In some examples, the multiple first holes 131 may be arranged at equal intervals in the second direction Y, and the multiple second holes 132 may be arranged at equal intervals in the second direction Y. Columns formed by the multiple first holes 131 and columns formed by the multiple second holes 132 may be arranged at intervals in the first direction X. In an example, one first hole 131 and a second hole 132 which is adjacent to the first hole 131 in the first direction X may have the same central axis, and the central axis is parallel to the first direction X. One first hole 131 and one second hole 132 which is adjacent to the first hole 131 in the first direction X may constitute a via group 130G, and multiple via groups 130G are arranged at intervals in the second direction Y. A spacing between the first hole 131 and the second hole 132 in one via group 130G is less than a spacing between two adjacent via groups 130G.

In some embodiments, a patterned mask layer (not shown in the figure) may be formed on the stacked structure 120, the patterned mask layer serves as a mask, and the stacked structure 120 is partially removed by a dry etching process to synchronously form the first holes 131 and the second holes 132. In another example, after a patterned first mask layer may alternatively be adopted to form the first holes 131 in the stacked structure 120, the patterned first mask layer is removed, and then a patterned second mask layer may be adopted to form the second holes 132 in the stacked structure 120.

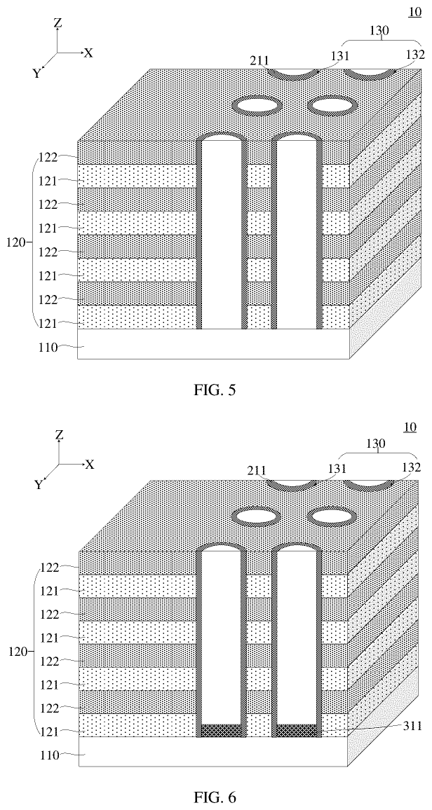

As shown in FIG. 4 and FIG. 5, a sidewall protective material layer 210 conformally covered is formed, by a deposition process, on an exposed surface of the stacked structure 120 on which the vias 130 are formed. After a part of the sidewall protective material layer 210 located on the top surface of the stacked structure 120 and located on the bottom of each of the vias 130 is removed, a sidewall protective layer 211 located on an inner wall of each of the vias 130 is retained. The material of the sidewall protective layer 211 may be an insulating material such as silicon oxide, silicon nitride, silicon oxynitride, silicon carbide, or the like. The sidewall protective layer 211 is configured to improve the uniformity of the material and the profile of the inner wall of each of the vias 130 in a subsequent process procedure, and can reduce impurity peeling.

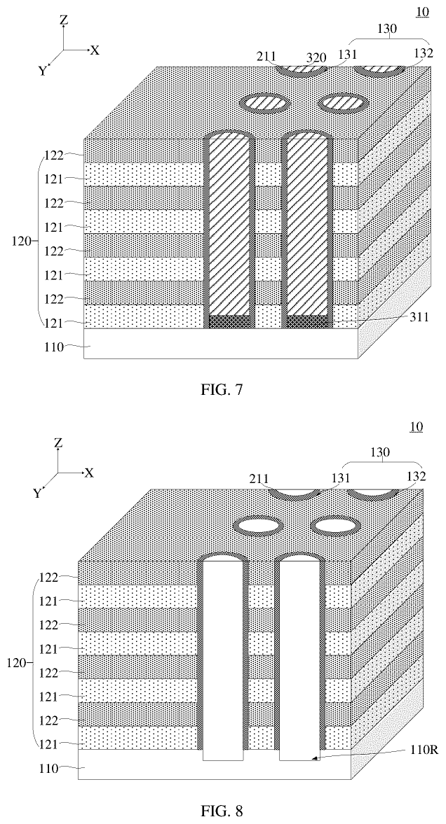

In some embodiments, as shown in FIG. 6, a bottom protective layer 311 is formed on the part of the surface of the substrate 110 exposed by the bottom of each of the vias 130. As shown in FIG. 7, each of the vias 130 is filled with an isolation layer 320. The thickness of the bottom protective layer 311 is less than the thickness of one of the first dielectric layers 121, that is, the top surface of the bottom protective layer 311 is lower than the top surface of the first dielectric layer 121 at a bottom layer. The first dielectric layer 121 at the bottom layer is the first dielectric layer 121 closest to the substrate 110.

The bottom protective layer 311 may be formed by an epitaxial growth process or a deposition process. For example, the substrate 110 is a monocrystalline silicon layer, and the bottom protective layer 311 may be a silicon germanium (SiGe) layer epitaxially grown on the monocrystalline silicon layer by the epitaxial growth process. By the epitaxial growth process, the silicon germanium layer may be selectively formed on a part of an exposed surface of the substrate 110, thereby effectively reducing a formation amount and a coverage area of the silicon germanium layer, and reducing germanium pollution caused by the silicon germanium layer. In addition, the silicon germanium layer formed by the epitaxial growth process can have good adhesion to the monocrystalline silicon layer, thereby effectively preventing the silicon germanium layer from peeling off.

The isolation layer 320 covers the sidewall protective layer 211 and the bottom protective layer 311 and completely fills each of the vias 130. An isolation material layer may be formed through deposition by a deposition process. A part of the isolation material layer located on the top surface of the stacked structure 120 is removed by a chemical mechanical polishing process, only the isolation material layer located in each of the vias 130 is retained as the isolation layer 320, and the top surface of the isolation layer 320 may be flush with the top surface of the stacked structure 120. The material of the isolation layer 320 is a material that has a relatively high etching selectivity with those of the first dielectric layers 121, the second dielectric layers 122, the bottom protective layer 311, and the sidewall protective layer 211. For example, the material of the isolation layer 320 may be polycrystalline silicon. The etching selectivity of polycrystalline silicon is close to that of the substrate 110. If the isolation layer 320 is directly formed on the substrate 110, damage to the substrate 110 is possibly caused in a procedure of removing the isolation layer 320, a recess of the substrate 110 is caused, and a risk of electric leakage is increased.

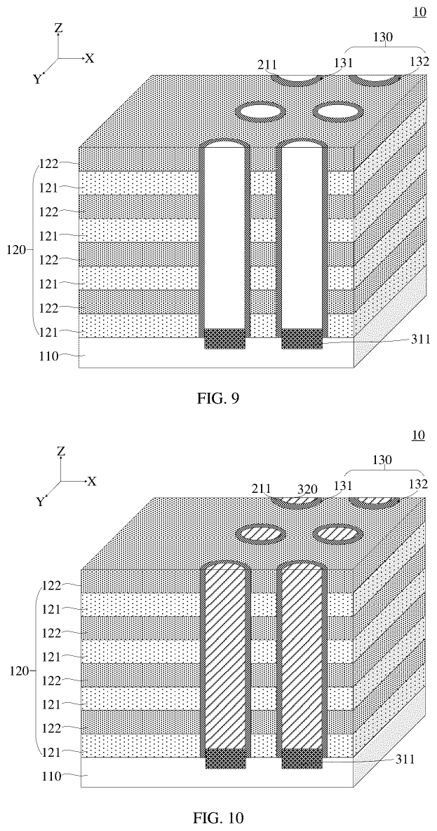

In some other embodiments, as shown in FIG. 8, a part of the substrate 110 may be further removed when the vias 130 are formed, so that a substrate recess 110R is formed on the surface of the substrate 110, that is, the bottom surface of the via 130 is lower than the top surface of the substrate 110. The height of the substrate recess 110R may be less than thicknesses of the first dielectric layers 121 or the second dielectric layers 122. As shown in FIG. 9, a bottom protective layer 311 is formed on the part of the surface of the substrate 110 exposed by the bottom of each of the vias 130. As shown in FIG. 10, each of the vias 130 is filled with an isolation layer 320, and the top surface of the bottom protective layer 311 is lower than the top surface of one of the first dielectric layers 121.

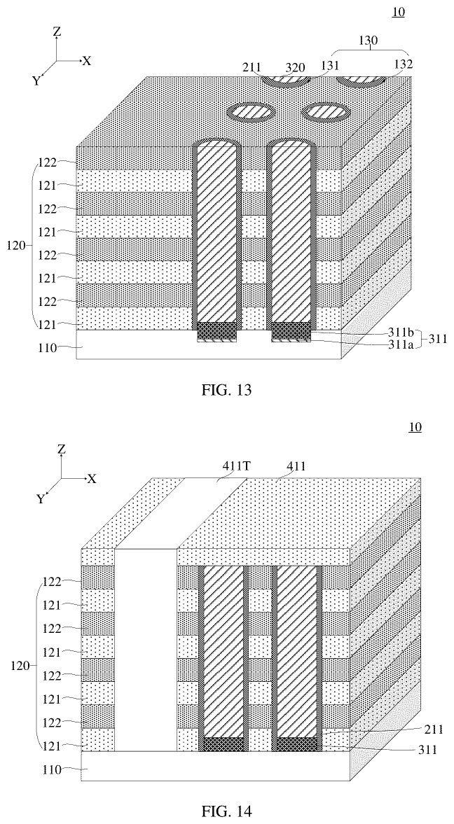

In some other embodiments, as shown in FIG. 11, a part of the substrate 110 may be further removed when the vias 130 are formed, so that a substrate recess 110R is formed on the surface of the substrate 110, and the bottom surface of each of the vias 130 is lower than the top surface of the substrate 110. That a bottom protective layer 311 is formed on the part of the surface of the substrate 110 exposed by each of the vias 130 includes the step as follows. A monocrystalline silicon layer 311a is formed by a first epitaxial growth process on the part of the surface of the substrate 110 exposed by each of the vias 130, where the top surface of the monocrystalline silicon layer 311a is lower than the top surface of the substrate 110. As shown in FIG. 12, a silicon germanium layer 311b is formed on the monocrystalline silicon layer 311a by a second epitaxial growth process, where the thickness of the monocrystalline silicon layer 311a is less than the thickness of the silicon germanium layer 311b. For example, the thickness of the monocrystalline silicon layer 311a ranges from 1 nm to 3 nm and the thickness of the silicon germanium layer 311b is from 3 nm to 6 nm. The monocrystalline silicon layer 311a and the silicon germanium layer 311b constitute the bottom protective layer 311. In addition, the monocrystalline silicon layer 311a helps increase adhesion between the silicon germanium layer 311b and the substrate 110, and prevents the silicon germanium layer 311b from peeling off. As shown in FIG. 13, each of the vias 130 is filled with an isolation layer 320, and the isolation layer 320 covers the top surface of the silicon germanium layer 311b. A precursor gas adopted in the first epitaxial growth process may be a silane-based semiconductor precursor gas, e.g., silane or disilane. A precursor gas adopted in the second epitaxial growth process may be a semiconductor precursor gas including germanium, e.g., disilane and germane.

In some embodiments, a bit line structure 412 may be first formed, and then a transistor structure 610 and a capacitor structure 510 are formed. Alternatively, the transistor structure 610 and the capacitor structure 510 may be first formed, and then the bit line structure 412 is formed. A sequence of forming the bit line structure 412, the transistor structure 610, and the capacitor structure 510 is not limited in the present disclosure. With reference to FIG. 2 to FIG. 7 and as shown in FIG. 14 to FIG. 21, in the present disclosure, that a bit line structure is first formed and then a transistor structure and a capacitor structure are formed is taken as an example for description.

As shown in FIG. 14, a patterned mask layer 411 is formed on the stacked structure 120, the patterned mask layer 411 has an etch opening, a part of the stacked structure 120 is removed along the etch opening, so that a linear trench 411T is formed on one side of each of the vias 130 in the first direction X. The linear trench 411T extends in the second direction Y, runs through the stacked structure 120 in the vertical direction Z, and exposes a part of the surface of the substrate 110.

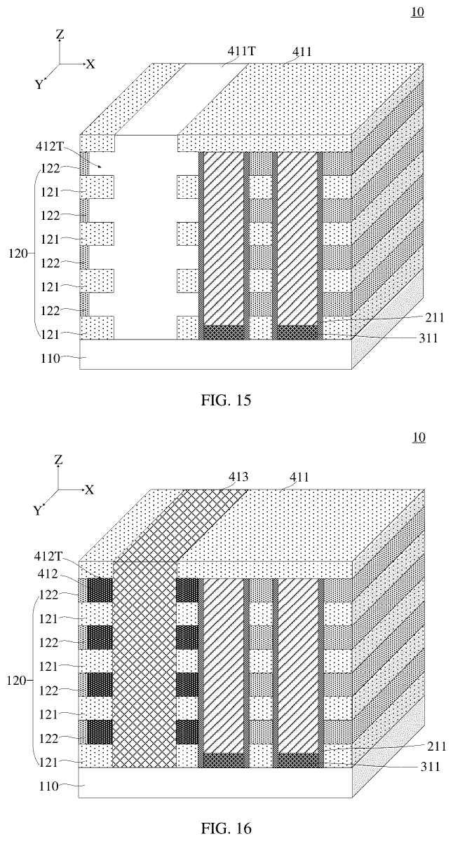

As shown in FIG. 15, a part of the second dielectric layers 122 are laterally removed along the linear trench 411T to form bit line trenches 412T, and the bit line trenches 412T are in communication with the linear trench 411T, and may be located on two sides of the linear trench 411T in the first direction X. Multiple bit line trenches 412T are arranged at intervals in the vertical direction Z, and the bit line trenches 412T adjacent in the vertical direction Z are separated by the first dielectric layers 121. A sidewall of each of the bit line trenches 412T may expose the sidewall protective layer 211 located at one end of the inner wall of each of the first holes 131 in the vias 130.

As shown in FIG. 16, bit line structures 412 filling the bit line trenches 412T are formed. The bit line structures 412 extend in the second direction Y, and the linear trench 411T is filled with a third dielectric layer 413. The material of the third dielectric layer 413 may be at least one of insulating materials such as silicon oxide, silicon nitride, silicon oxynitride, silicon carbide, and the like.

In some embodiments, the bit line structures 412 may be formed of conductive materials. The conductive materials may include one or more of the following: metals (e.g., tungsten (W), titanium (Ti), molybdenum (MO), niobium (Nb), vanadium (V), hafnium (Hf), tantalum (Ta), chromium (Cr), zirconium (Zr), iron (Fe), ruthenium (Ru), cobalt (Co), and nickel (Ni)); alloys (e.g., a Co-based alloy, a Ti-based alloy, a Co—Ni-based alloy, and a Fe—Co-based alloy); conductive metal materials (e.g., a conductive metal nitride, a conductive metal silicide, a conductive metal carbide, and a conductive metal oxide); and conductive doped semiconductor materials (e.g., conductive doped polycrystalline silicon and conductive doped silicon germanium). The bit line structures 412 each may be a single-layer structure or a multi-layer structure. For example, the bit line structure 412 may be a multi-layer structure including a conductive metal silicide layer, a titanium nitride layer, and a tungsten layer. The conductive metal silicide layer is disposed in a direct contact connection to the sidewall protective layer 211, to subsequently reduce the contact resistance of the bit line structure 412 and the transistor structure.

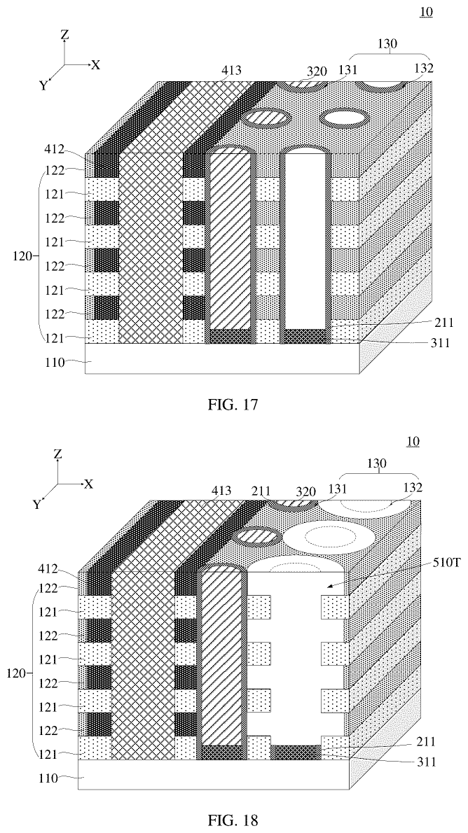

In some embodiments, as shown in FIG. 17 to FIG. 20, forming a capacitor structure 510 in each of the second holes 132 includes the steps as follows. A part of the second dielectric layers 122 are laterally removed along the second holes 132 to form capacitor trenches 510T; bottom electrode layers 511 covering inner walls of the capacitor trenches 510T are formed; capacitor dielectric layers 512 covering the bottom electrode layers 511 are formed, where the capacitor dielectric layers 512 cover the bottom protective layers 311 at the bottoms of the second holes 132; and upper electrode layers 513 covering the capacitor dielectric layers 512 and filling the second holes 132 are formed.

As shown in FIG. 17, after the mask layer 411 is removed, the isolation layer 320 located in each of the second holes 132 is removed by an etching process, to expose the sidewall protective layer 211 located in each of the second holes 132 and the bottom protective layer 311. The etching process includes a dry etching process or a wet etching process. In an example, the material of the isolation layer 320 is polycrystalline silicon. The isolation layer 320 is removed by adopting an ammonia diw mixture (ADM) and/or tetramethylammonium hydroxide (TMAH, (CH₃)₄NOH). Because the ammonia diw mixture and the tetramethylammonium hydroxide have relatively low etching selectivity to silicon nitride, silicon oxide, silicon germanium, and the like, etching selectivity ratios of the isolation layer 320, the bottom protective layer 311, and the sidewall protective layer 211 are all greater than 10:1. Therefore, damage to the sidewall protective layer 211, the bottom protective layer 311, and the substrate 110 can be avoided in a procedure of removing the isolation layer 320 in each of the second holes 132.

As shown in FIG. 18, a part of the sidewall protective layer 211 in each of the second holes 132 is removed, and a part of the sidewall protective layer 211 covered by the bottom protective layer 311 is retained. The second holes 132 expose the first dielectric layers 121 and the second dielectric layers 122. The part of the second dielectric layers 122 are laterally removed along the second holes 132 to form the capacitor trenches 510T. A sidewall of each of the capacitor trenches 510T may expose the sidewall protective layer 211 located at the other end of the inner wall of each of the first holes 131 in the vias 130, and the capacitor trenches 510T arranged in the second direction Y are separated from each other.

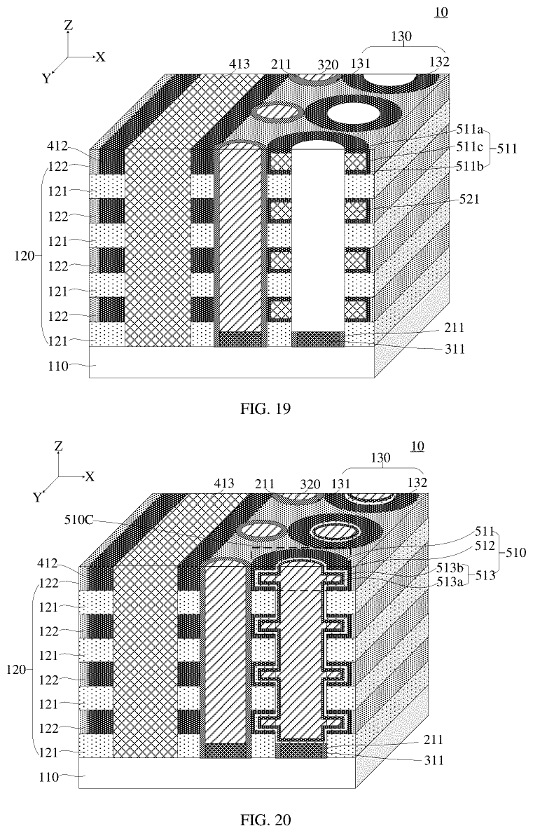

As shown in FIG. 19, initial bottom electrode layers covering the inner walls of the capacitor trenches 510T are formed, bottom electrode protective layers 521 covering the initial bottom electrode layers and filling the capacitor trenches 510T are filled, a part of the initial bottom electrode layers are removed, the bottom electrode layers 511 located only on the inner walls of the capacitor trenches 510T are retained, and multiple bottom electrode layers 511 are arranged at intervals in the vertical direction Z. The projection of each of the bottom electrode layers 511 on the substrate 110 is in a shape of a ring, and each of the bottom electrode layers 511 may include an upper parallel portion 511a, a lower parallel portion 511b, and a vertical portion 511c connecting the upper parallel portion 511a and the lower parallel portion 511b. The projections of the upper parallel portion 511a and the lower parallel portion 511b on the substrate 110 are in shapes of rings overlapping with each other, and the vertical portion 511c connects the outer edges of the upper parallel portion 511a and the lower parallel portion 511b. The thicknesses of the upper parallel portion 511a and the lower parallel portion 511b in the vertical direction Z may be equal to the thickness of the vertical portion 511c in the horizontal direction. The vertical portion 511c is in contact with the sidewall protective layer 211 located in each of the first holes 131.

As shown in FIG. 20, the bottom electrode protective layers 521 are removed, the capacitor dielectric layers 512 covering the bottom electrode layers 511 are formed through conformal deposition, the capacitor dielectric layers 512 cover the bottom protective layers 311 at the bottoms of the second holes 132 and the retained sidewall protective layer 211, and the upper electrode layers 513 covering the capacitor dielectric layers 512 and filling the second holes 132 are formed through conformal deposition. The upper electrode layers 513 may include first upper electrode layers 513a and second upper electrode layers 513b. The first upper electrode layers 513a conformally cover the capacitor dielectric layers 512, and the second upper electrode layers 513b cover the first upper electrode layers 513a and fill the second holes 132. The second upper electrode layers 513b may have columnar portions extending in the vertical direction Z and protruding portions protruding horizontally along sidewalls of the columnar portions, the columnar portions run through the stacked structure 120, and the protruding portions are inserted into the capacitor trenches 510T. The bottom electrode layer 511, the capacitor dielectric layer 512, and the upper electrode layer 513 located in each capacitor trench 510T together constitute a capacitor unit 510C. The capacitor structure 510 in each of the second holes 132 includes multiple capacitor units 510C disposed at intervals in the vertical direction Z.

The bottom electrode layers 511, the first upper electrode layers 513a, and the second upper electrode layers 513b may be formed of conductive materials. The materials of the first upper electrode layers 513a and the second upper electrode layers 513b may be different. For example, the second upper electrode layers 513b may be conductive doped polycrystalline silicon layers or conductive doped silicon germanium layers. The capacitor dielectric layers 512 may be formed of high dielectric constant materials. The high dielectric constant materials may include one or more of the following: hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminium oxide, lead scandium tantalum oxide, lead zinc niobate, and the like.

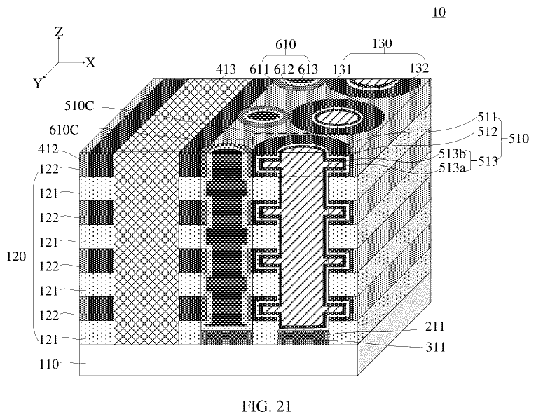

In some embodiments, as shown in FIG. 21, forming a transistor structure 610 in each of the first holes 131 includes the steps as follows. A channel layer 611 is formed on a sidewall of each of the first holes 131 corresponding to each of the second dielectric layers 122; a gate dielectric layer 612 covering the channel layer 611 is formed, where the gate dielectric layer 612 covers the top surface of the bottom protective layer 311 at the bottom of each of the first holes 131; and a gate structure 613 filling each of the first holes 131 is formed, where the projection of the channel layer 611 in a direction perpendicular to the vertical direction Z is in a shape of a ring surrounding the gate structure 613.

As shown in FIG. 20 and FIG. 21, the isolation layer 320 located in each of the first holes 131 is removed by an etching process, to expose the sidewall protective layer 211 located in each of the first holes 131 and the bottom protective layer 311. In an example, the material of the isolation layer 320 is polycrystalline silicon. The isolation layer 320 is removed by adopting an ammonia diw mixture and/or tetramethylammonium hydroxide. Because the ammonia diw mixture and the tetramethylammonium hydroxide have relatively low etching selectivity to silicon nitride, silicon oxide, silicon germanium, and the like. Therefore, damage to the sidewall protective layer 211, the bottom protective layer 311, and the substrate 110 can be avoided in a procedure of removing the isolation layer 320 in each of the first holes 131.

As shown in FIG. 21, a part of the sidewall protective layer 211 in each of the first holes 131 is removed, and a part of the sidewall protective layer 211 covered by the bottom protective layer 311 is retained. The first holes 131 expose the bit line structures 412 and the bottom electrode layers 511 of the capacitor structures 510 that are on layers on which the second dielectric layers 122 are located, and each of the bit line structures 412 and each of the bottom electrode layers 511 are respectively located at two ends of each of the first holes 131 in the first direction X. The channel layer 611 is formed on the sidewall of each of the first holes 131. The channel layer 611, the gate dielectric layer 612, and the gate structure 613 together constitute the transistor structure 610, the transistor structure 610 in each of the first holes 131 includes multiple transistor units 610C disposed at intervals in the vertical direction Z, and the transistor units 610C are electrically connected to the capacitor units 510C one by one to form a 1T1C (One-transistor, one-capacitor) horizontal cell.

In some embodiments, the channel layer 611 may completely cover the sidewall of each of the first hole 131.

In some embodiments, as shown in FIG. 21, after a channel material layer completely covering the sidewall of each of the first holes 131 is deposited, a part of the channel material layer located on the sidewall of each of the first holes 131 corresponding to each of the first dielectric layers 121 further needs to be removed, and the retained channel layer 611 is located only on the sidewall of each of the first holes 131 corresponding to each of the second dielectric layers 122, thereby reducing coupling between adjacent ones of the transistor units 610C in the vertical direction Z. In addition, the second dielectric layers 122 corresponding to each of the first holes 131 may be partially removed, so that the subsequently formed gate structure 613 has a sawtooth profile. To be specific, the size of each of first parts of the gate structure 613 surrounded by the channel layer 611 is larger than the size of a second part between the first parts, and the second part is not surrounded by the channel layer 611, so that an area of a directly facing region between the gate structure 613 and the channel layer 611 can be increased, thereby enhancing the control capability of the gate structure 613 for the channel layer 611.

In some embodiments, the gate dielectric layer 612 may alternatively cover only the channel layer 611, or the gate dielectric layer 612 may cover the channel layer 611 and the sidewall of each of the first dielectric layers 121 exposed by each of the first holes 131.

Based on the foregoing fabrication method for a semiconductor structure 10, an embodiment of the present disclosure further provides a semiconductor structure 10. FIG. 21 is a schematic diagram of a semiconductor structure 10 according to an embodiment of the present disclosure.

As shown in FIG. 21, the semiconductor structure 10 includes: a substrate 110 and a stacked structure 120 located on the surface of the substrate 110, where the stacked structure 120 includes first dielectric layers 121 and second dielectric layers 122 stacked in the vertical direction Z; vias 130 running through the stacked structure 120 in the vertical direction Z, where the vias 130 include first holes 131 and second holes 132; a bottom protective layer 311 located at the bottom of each of the vias 130 and a sidewall protective layer 211 surrounding the bottom protective layer 311, where the bottom protective layer 311 is in contact with the substrate 110; a transistor structure 610 located in each of the first holes 131; and a capacitor structure 510 located in each of the second holes 132, where the capacitor structure 510 is electrically connected to the transistor structure 610.

By disposing the bottom protective layer 311 located at the bottoms of the transistor structure 610 and the capacitor structure 510 and the sidewall protective layer 211 surrounding the bottom protective layer 311, electric leakage between the substrate and each of the transistor structure 610 and the capacitor structure 510 can be effectively reduced, and the electrical stability of the semiconductor structure can be improved. Because the sidewall protective layer 211 of the bottom protective layer 311 is located only on a part of the surface of the substrate 110 but not on the entire surface of the substrate 110, it may not bring a relatively large stress to the semiconductor structure as a whole. In addition, it can avoid over etching damage to the substrate and impurity peeling in a procedure of forming the semiconductor structure, thereby improving the structural stability of the semiconductor structure.

In some embodiments, the top surface of the sidewall protective layer 211 is flush with or higher than the top surface of the bottom protective layer 311. The bottom protective layer 311 may be formed by an epitaxial growth process, and the material of the bottom protective layer 311 may include silicon germanium.

In some embodiments, as shown in FIG. 8 or FIG. 11, a substrate recess 110R is formed on the surface of the substrate 110, and the bottom protective layer 311 and the sidewall protective layer 211 are located on the substrate recess 110R.

In some embodiments, as shown in FIG. 13, the bottom protective layer 311 includes a monocrystalline silicon layer 311a and a silicon germanium layer 311b located on the monocrystalline silicon layer 311a, the top surface of the monocrystalline silicon layer 311a is lower than the top surface of the substrate, the top surface of the silicon germanium layer 311b is lower than the top surface of the first dielectric layer 121 located closest to the substrate 110, and the thickness of the monocrystalline silicon layer 311a is less than the thickness of the silicon germanium layer 311b. For example, the top surface of the bottom protective layer 311 is located between 0.3 and 0.6 of the height of the first dielectric layer 121 located closest to the substrate 110, so that protection to the substrate 110 can be ensured while avoiding spatial impact on the transistor structure 610 and the capacitor structure 510.

In some embodiments, as shown in FIG. 3 and FIG. 21, the vias 130 include multiple via groups 130G arranged in a second direction Y, and each via group 130G includes one of the first holes 131 and one of the second holes 132 arranged in a first direction X; the transistor structure 610 in each of the first holes 131 includes multiple transistor units 610C disposed at intervals in the vertical direction Z; the capacitor structure 510 in each of the second holes 132 includes multiple capacitor units 510C disposed at intervals in the vertical direction Z; the semiconductor structure 10 further includes bit line structures 412, the bit line structures 412 extend in the second direction Y, multiple ones of the bit line structures 412 are arranged at intervals in the vertical direction Z, and each of the bit line structures 412 is electrically connected to multiple ones of the transistor units 610C located at the same layer.

In some embodiments, as shown in FIG. 21, the transistor structure 610 includes: a channel layer 611, located on a sidewall of each of the first holes 131 corresponding to each of the second dielectric layers 122; a gate dielectric layer 612, covering the channel layer, the sidewall of each of the first holes 131 corresponding to each of the second dielectric layers 122, and the top surface of the bottom protective layer 311; and a gate structure 613, extending in the vertical direction Z and filling each of the first holes 131, where the projection of the channel layer 611 in a direction perpendicular to the vertical direction Z is in a shape of a ring surrounding the gate structure 613.

Two ends of the channel layer 611 in the first direction X is respectively electrically connected to the bit line structure 412 and the capacitor structure 510. The material of the channel layer 611 may be monocrystalline silicon, polycrystalline silicon, germanium, silicon germanium, and an oxide semiconductor material (e.g., zinc tin oxide (ZnₓSn_{y}O, commonly known as “ZTO”), indium zinc oxide (InₓZn_{y}O, commonly known as “IZO”), zinc oxide (ZnO), indium gallium zinc oxide (InₓGa_{y}Zn_{z}O, commonly known as “IGZO”), indium gallium silicon oxide (InₓGa_{y}Si_{z}O, commonly known as “IGSO”), indium tin oxide (InₓSn_{y}O, commonly known as “ITO”), and one or more of other similar materials).

The transistor structure 610 in each of the first holes 131 includes multiple transistor units 610C disposed at intervals in the vertical direction Z, and the multiple transistor units 610C are respectively located at layers at which the second dielectric layers 122 in the stacked structure 120 are located. The gate structure 613 extends in the vertical direction Z, and runs through the stacked structure 120. The bottom surface of the gate structure 613 is lower than the top surface of the first dielectric layer 121 at the bottom layer.

In some embodiments, as shown in FIG. 21, the capacitor structure 510 includes: bottom electrode layers 511, located on a sidewall of each of the second holes 132 corresponding to each of the second dielectric layers 122, where the projection of each of the bottom electrode layers 511 in a direction perpendicular to the vertical direction Z is in a shape of a ring; a capacitor dielectric layer 512, where the capacitor dielectric layer 512 covers the bottom protective layer 311 at the bottom of each of the second holes 132; and an upper electrode layer 513, covering the capacitor dielectric layer 512 and filling each of the second holes 132.

The capacitor structure 510 in each of the second holes 132 includes multiple capacitor units 510C disposed at intervals in the vertical direction Z, the multiple capacitor units 510C are respectively located at layers at which the second dielectric layers 122 in the stacked structure 120 are located, and the transistor units 610C are electrically connected to the capacitor units 510C one by one to form a 1T1C horizontal cell.

In some embodiments, as shown in FIG. 19, the projection of the bottom electrode layer 511 on the substrate 110 is in a shape of a ring, and the bottom electrode layer 511 may include an upper parallel portion 511a, a lower parallel portion 511b, and a vertical portion 511c connecting the upper parallel portion 511a and the lower parallel portion 511b. The projections of the upper parallel portion 511a and the lower parallel portion 511b on the substrate 110 are in shapes of rings overlapping with each other, and the vertical portion 511c connects the outer edges of the upper parallel portion 511a and the lower parallel portion 511b. The thicknesses of the upper parallel portion 511a and the lower parallel portion 511b in the vertical direction Z may be equal to the thickness of the vertical portion 511c in the horizontal direction. The vertical portion 511c is in contact with the channel layer 611 located in each of the first holes 131.

In some embodiments, the first upper electrode layer 513a conformally covers the capacitor dielectric layer 512, and the second upper electrode layer 513b covers the first upper electrode layer 513a and fills the second holes 132. The second upper electrode layer 513b may have a columnar portion extending in the vertical direction Z and a protruding portion protruding horizontally along a sidewall of the columnar portion, the columnar portion runs through the stacked structure 120, and the protruding portion is inserted into a capacitor trench 510T. The bottom surface of the second upper electrode layer 513b is lower than the top surface of the first dielectric layer 121 at the bottom layer.

In some embodiments, the semiconductor structure 10 includes a memory. The memory may be a dynamic random access memory, e.g., a three-dimensional memory, 3D DRAM. Alternatively, the memory may be a memory known in the art, e.g., a phase change memory or a ferroelectric memory.

Various semiconductor structures shown in the specific implementations may be utilized in electronic devices with a storage function. Each of the electronic devices may be a terminal device, e.g., a mobile phone, a tablet computer, or a mart wristband, or may be a personal computer (PC), a server, or a workstation. The storage function in the electronic devices may be implemented by the following memory: a dynamic random access memory (DRAM), a ferroelectric random access memory (FRAM), a phase change memory (PCM), a magnetic random access memory (MRAM), or a resistive random access memory (RRAM).

The foregoing descriptions are merely specific implementations of the present disclosure, but are not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

1. A fabrication method for a semiconductor structure, comprising:
providing a substrate and a stacked structure formed on the substrate, the stacked structure comprising first dielectric layers and second dielectric layers stacked in a vertical direction;
forming vias running through the stacked structure in the vertical direction, the vias comprising first holes and second holes, each of the vias exposing a partial surface of the substrate, and a bottom surface of each of the vias being flush with or lower than a top surface of the substrate;
forming a sidewall protective layer on an inner wall of each of the vias;
forming a bottom protective layer on the partial surface of the substrate exposed by each of the vias;
filling each of the vias with an isolation layer;
removing the isolation layer and a part of the sidewall protective layer in each of the first holes, and forming a transistor structure in each of the first holes; and
removing the isolation layer and a part of the sidewall protective layer in each of the second holes, and forming a capacitor structure in each of the second holes, the capacitor structure being electrically connected to the transistor structure.

2. The fabrication method according to claim 1, wherein the stacked structure comprises the first dielectric layers and the second dielectric layers alternately stacked in the vertical direction, the bottom layer of the stacked structure is one of the first dielectric layer, and the top layer of the stacked structure is one of the second dielectric layer.

3. The fabrication method according to claim 1, wherein the forming vias running through the stacked structure in the vertical direction comprises:
partially removing the stacked structure by a dry etching process to synchronously form the first holes and the second holes.

4. The fabrication method according to claim 1, wherein during forming of the vias running through the stacked structure in the vertical direction, the method comprises:
removing a part of the substrate to form a substrate recess on a surface of the substrate, wherein the bottom surface of each of the vias is lower than the top surface of the substrate.

5. The fabrication method according to claim 1, wherein the bottom surface of each of the vias is lower than the top surface of the substrate, and the forming a bottom protective layer on the partial surface of the substrate exposed by each of the vias comprises:
forming, by a first epitaxial growth process, a monocrystalline silicon layer on the part of the surface of the substrate exposed by each of the vias, wherein a top surface of the monocrystalline silicon layer is lower than the top surface of the substrate; and
forming a silicon germanium layer on the monocrystalline silicon layer by a second epitaxial growth process, wherein a thickness of the monocrystalline silicon layer is less than a thickness of the silicon germanium layer.

6. The fabrication method according to claim 1, wherein the forming a transistor structure in each of the first holes comprises:
forming a channel layer on a sidewall of each of the first holes corresponding to each of the second dielectric layers;
forming a gate dielectric layer covering the channel layer, wherein the gate dielectric layer covers a top surface of the bottom protective layer at a bottom of each of the first holes; and
forming a gate structure filling each of the first holes, wherein a projection of the channel layer in a direction perpendicular to the vertical direction is in a shape of a ring surrounding the gate structure.

7. The fabrication method according to claim 1, wherein the forming a capacitor structure in each of the second holes comprises:
laterally removing a part of the second dielectric layers along the second holes to form capacitor trenches;
forming bottom electrode layers covering inner walls of the capacitor trenches;
forming capacitor dielectric layers covering the bottom electrode layers, wherein the capacitor dielectric layers cover the bottom protective layers at bottoms of the second holes; and
forming upper electrode layers covering the capacitor dielectric layers and filling the second holes.

8. The fabrication method according to claim 1, wherein the vias comprise a plurality of via groups arranged in a second direction, and each via group comprises one of the first holes and one of the second holes arranged in a first direction; the transistor structure in each of the first holes comprises a plurality of transistor units disposed at intervals in the vertical direction; the capacitor structure in each of the second holes comprises a plurality of capacitor units disposed at intervals in the vertical direction; and the method further comprises:
forming a linear trench on one side of each of the vias in the first direction;
laterally removing a part of the second dielectric layers along the linear trench to form bit line trenches; and
forming bit line structures filling the bit line trenches, wherein the bit line structures extend in the second direction, a plurality ones of the bit line structures are arranged at intervals in the vertical direction, and each of the bit line structures is electrically connected to a plurality ones of the transistor units located at a same layer.

9. The fabrication method according to claim 8, wherein a spacing between the first hole and the second hole in one via group is less than a spacing between two adjacent via groups.

10. A semiconductor structure, comprising:
a substrate and a stacked structure located on a surface of the substrate, the stacked structure comprising first dielectric layers and second dielectric layers stacked in a vertical direction;
vias running through the stacked structure in the vertical direction, the vias comprising first holes and second holes;
a bottom protective layer located at a bottom of each of the vias and a sidewall protective layer surrounding the bottom protective layer, the bottom protective layer being in contact with the substrate;
a transistor structure located in each of the first holes; and
a capacitor structure located in each of the second holes, the capacitor structure being electrically connected to the transistor structure.

11. The semiconductor structure according to claim 10, wherein the vias comprise a plurality of via groups arranged in a second direction, and each via group comprises one of the first holes and one of the second holes arranged in a first direction;
the transistor structure in each of the first holes comprises a plurality of transistor units disposed at intervals in the vertical direction;
the capacitor structure in each of the second holes comprises a plurality of capacitor units disposed at intervals in the vertical direction; and
the semiconductor structure further comprises bit line structures, the bit line structures extend in the second direction, a plurality ones of the bit line structures are arranged at intervals in the vertical direction, and each of the bit line structures is electrically connected to a plurality ones of the transistor units located at a same layer.

12. The semiconductor structure according to claim 11, wherein the transistor structure comprises:
a channel layer, located on a sidewall of each of the first holes corresponding to each of the second dielectric layers;
a gate dielectric layer, covering the channel layer, the sidewall of each of the first holes corresponding to each of the second dielectric layers, and a top surface of the bottom protective layer; and
a gate structure, extending in the vertical direction and filling each of the first holes, wherein a projection of the channel layer in a direction perpendicular to the vertical direction is in a shape of a ring surrounding the gate structure.

13. The semiconductor structure according to claim 10, wherein the capacitor structure comprises:
bottom electrode layers, located on a sidewall of each of the second holes corresponding to each of the second dielectric layers, wherein a projection of each of the bottom electrode layers in a direction perpendicular to the vertical direction is in a shape of a ring;
a capacitor dielectric layer, wherein the capacitor dielectric layer covers the bottom protective layer at a bottom of each of the second holes; and
an upper electrode layer, covering the capacitor dielectric layer and filling each of the second holes.

14. The semiconductor structure according to claim 10, wherein the bottom protective layer comprises a monocrystalline silicon layer and a silicon germanium layer located on the monocrystalline silicon layer, a top surface of the monocrystalline silicon layer is lower than a top surface of the substrate, a top surface of the silicon germanium layer is lower than a top surface of the first dielectric layer located closest to the substrate, and a thickness of the monocrystalline silicon layer is less than a thickness of the silicon germanium layer.

15. The semiconductor structure according to claim 14, wherein the thickness of the monocrystalline silicon layer ranges from 1 nm to 3 nm and the thickness of the silicon germanium layer is from 3 nm to 6 nm.

16. The semiconductor structure according to claim 13, wherein the bottom electrode layer comprises an upper parallel portion, a lower parallel portion, and a vertical portion connecting the upper parallel portion and the lower parallel portion, and the vertical portion is in contact with the transistor structure located in each of the first holes.

17. The semiconductor structure according to claim 10, wherein a substrate recess is formed on the surface of the substrate, and the bottom protective layer and the sidewall protective layer are located on the substrate recess.

18. The semiconductor structure according to claim 12, wherein a size of each of first parts of the gate structure surrounded by the channel layer is larger than a size of a second part of the gate structure between the first parts.
